(19) United States
(12) Patent Application Publication
(10) Pub. No.: US 2024/0258396 A1
(43) Pub. Date: Aug. 1, 2024

(54) SEMICONDUCTOR DEVICE

(71) Applicant: Samsung Electronics Co., Ltd., Suwon-si (KR)

(72) Inventors: Jun Ki PARK, Suwon-si (KR); Seon-Bae KIM, Suwon-si (KR); Sung Hwan KIM, Suwon-si (KR); Wan Don KIM, Suwon-si (KR); Jin Young PARK, Suwon-si (KR)

(73) Assignee: Samsung Electronics Co., Ltd., Suwon-si (KR)

(21) Appl. No.: 18/458,438

(22) Filed: Aug. 30, 2023

(30) Foreign Application Priority Data
Feb. 1, 2023 (KR) 10-2023-0013559

(51) Int. Cl. H01L 29/45; H01L 27/088; H01L 29/06; H01L 29/417; H01L 29/423; H01L 29/775; H01L 29/786

(52) U.S. Cl. CPC H01L 29/456; H01L 27/088; H01L 29/0673; H01L 29/41775; H01L 29/42392; H01L 29/775; H01L 29/78696

(57) ABSTRACT

A semiconductor device may include gate structures spaced apart from each other on an active pattern, where each of the gate structures includes gate spacers on sidewalls of a gate electrode, source/drain patterns between the gate structures, source/drain contacts on the source/drain patterns, and contact silicide films between the source/drain contacts and the source/drain patterns. Outer surfaces of the contact silicide films may contact the source/drain patterns and inner surfaces of the contact silicide films may contact the source/drain contacts. A width in a first direction of the contact silicide films may be maximum at the uppermost portions of outer surfaces of the contact silicide films. Parts of the outer surfaces of the contact silicide films may contact the gate spacers. The width in the first direction of the uppermost portions of the contact silicide films may be equal to a width in the first direction of the source/drain contacts.

### CROSS-REFERENCE TO RELATED APPLICATION

This application claims priority from Korean Patent Application No. 10-2023-0013559 filed on Feb. 1, 2023 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a semiconductor device.

### Description of Related Art

As a scaling technique for increasing the density of a semiconductor device, a multi-gate transistor has been suggested in which a fin-type or nanowire-type multi-channel active pattern (or silicon body) is formed on a substrate and a gate is formed on the surface of the multi-channel active pattern.

Since the multi-gate transistor uses a three-dimensional (3D) channel, scaling can be facilitated. Also, current control capability can be improved without increasing the length of the gate of the multi-gate transistor. Also, a short channel effect (SCE), e.g., the phenomenon of the potential of a channel region being affected by a drain voltage, can be effectively limited and/or suppressed.

### SUMMARY

Aspects of the present disclosure provide a semiconductor device capable of improving performance and/or reliability by limiting and/or preventing short circuits between contact silicide films and gate electrodes.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an example embodiment of the present disclosure, a semiconductor device may include an active pattern extending in a first direction; a plurality of gate structures on the active pattern and spaced apart from one another in the first direction, each of the plurality of gate structures including a gate electrode extending in a second direction and gate spacers on sidewalls of the gate electrode; source/drain patterns between the plurality of gate structures that are adjacent to one another; source/drain contacts on the source/drain patterns and connected to the source/drain patterns; and contact silicide films between the source/drain contacts and the source/drain patterns. Outer surfaces of the contact silicide films may be in contact with the source/drain patterns and inner surfaces of the contact silicide films may be in contact with the source/drain contacts. Uppermost portions of the outer surfaces of the contact silicide films may be uppermost portions of the contact silicide films. A width in the first direction of the contact silicide films may reach its maximum at the uppermost portions of outer surfaces of the contact silicide films. Parts of the outer surfaces of the contact silicide films may be in contact with the gate spacers. The width in the first direction of the contact silicide films at the uppermost portions of the contact silicide films may be equal to a width in the first direction of the source/drain contacts.

According to an example embodiment of the present disclosure, a semiconductor device may include an active pattern including a lower pattern and a plurality of sheet patterns, the lower pattern extending in a first direction on a substrate, the plurality of sheet patterns being spaced apart from the lower pattern in a second direction, and the plurality of sheet patterns including an uppermost sheet pattern; a plurality of gate structures on the lower pattern and spaced apart from one another in the first direction, each of the plurality of gate structures including a gate electrode extending in a third direction and gate spacers on sidewalls of the gate electrode; source/drain patterns on the lower pattern and connected to the plurality of sheet patterns; source/drain contacts on the source/drain patterns and connected to the source/drain patterns; and contact silicide films between the source/drain contacts and the source/drain patterns. Outer surfaces of the contact silicide films may be in contact with the source/drain pattern, and inner surfaces of the contact silicide films may be in contact with the source/drain contacts. Inner sidewalls of the gate spacers may face the gate electrode and outer sidewalls of the gate spacers may be opposite the inner sidewalls in the first direction. Parts of the outer surfaces of the contact silicide films may be in contact with the outer sidewalls of the gate spacers. A width in the first direction of the contact silicide films may increase as a distance of the contact silicide films away from the substrate increases. A width in the first direction of the contact silicide films at uppermost portions of the contact silicide films may be equal to a width in the first direction of the source/drain contacts.

According to an example embodiment of the present disclosure, a semiconductor device an active pattern including a lower pattern and a plurality of sheet patterns, the lower pattern extending in a first direction, the plurality of sheet patterns being spaced apart from the lower pattern in a second direction, and the plurality of sheet patterns including an uppermost sheet pattern; a plurality of gate structures on the lower pattern and spaced apart from one another in the first direction, each of the plurality of gate structures including a gate electrode extending in a third direction and gate spacers on sidewalls of the gate electrode; source/drain patterns on the lower pattern and connected to the plurality of sheet patterns; source/drain contacts on the source/drain patterns and connected to the source/drain patterns; and contact silicide films between the source/drain contacts and the source/drain patterns. Outer surfaces of the contact silicide films may be in contact with the source/drain patterns. Inner surfaces of the contact silicide films in contact with the source/drain contacts. Upper surfaces of the contact silicide films may connect the outer surfaces of the contact silicide films and the inner surfaces of the contact silicide films. A height from lowermost portions of the source/drain patterns to uppermost portions of the contact silicide films may be greater than a height from the lowermost portions of the source/drain patterns to an upper surface of the uppermost sheet pattern. Uppermost portions of the outer surfaces of the contact silicide films may be higher than uppermost portions of the inner surfaces of the contact silicide films. The outer surfaces of the contact silicide films may be convex. The inner surfaces of the contact silicide films may be concave. In a cross-sectional view, the upper surfaces of the contact silicide films may be planes inclined with respect to the upper surface of the uppermost sheet pattern.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout view of a semiconductor device according to some embodiments of the present disclosure.

FIGS. 2 through 4 are cross-sectional views taken along lines A-A, B-B, and C-C of FIG. 1.

FIG. 5 is an enlarged cross-sectional view of part P of FIG. 2.

FIG. 6 is a cross-sectional view of a semiconductor device according to some embodiments of the present disclosure.

FIGS. 7 and 8 are cross-sectional views of a semiconductor device according to some embodiments of the present disclosure.

FIGS. 9 and 10 are cross-sectional views of a semiconductor device according to some embodiments of the present disclosure.

FIGS. 11 and 12 are cross-sectional views of a semiconductor device according to some embodiments of the present disclosure.

FIGS. 13 and 14 are cross-sectional views of a semiconductor device according to some embodiments of the present disclosure.

FIGS. 15 and 16 are cross-sectional views of a semiconductor device according to some embodiments of the present disclosure.

FIG. 17 is a cross-sectional view of a semiconductor device according to some embodiments of the present disclosure.

FIG. 18 is a cross-sectional view of a semiconductor device according to some embodiments of the present disclosure.

FIGS. 19 through 21 are cross-sectional views of a semiconductor device according to some embodiments of the present disclosure.

FIG. 22 is a cross-sectional view of a semiconductor device according to some embodiments of the present disclosure.

FIG. 23 is a cross-sectional view of a semiconductor device according to some embodiments of the present disclosure.

FIGS. 24 and 25 are cross-sectional views of a semiconductor device according to some embodiments of the present disclosure.

### DETAILED DESCRIPTION

It will be understood that, although the terms “first,” “second,” “upper,” “lower,” and the like may be used herein to describe various elements, these elements should not be limited by these terms. These terms are only used to distinguish one element from another. Thus, a “first” element discussed below could also be termed a “second” element without departing from the teachings of the present disclosure.

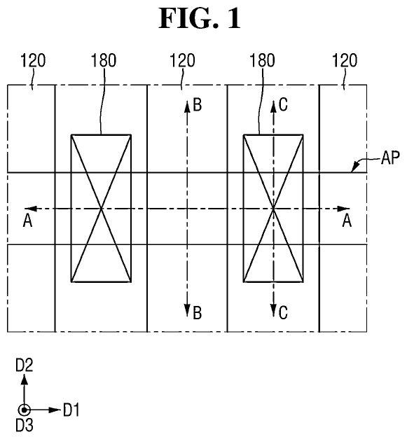

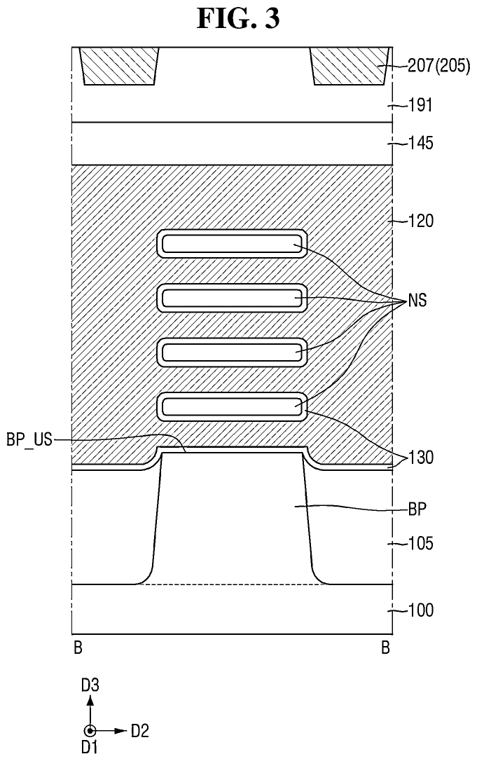

FIGS. 1 through 25 illustrate semiconductor devices according to some embodiments of the present disclosure as including fin field-effect transistors (FinFETs) including fin-type channel regions, transistors including nanowires or nanosheets, or multibridge channel field-effect transistors (MBCFETs), but the present disclosure is not limited thereto.

The semiconductor devices according to some embodiments of the present disclosure may include tunneling field-effect transistors (FETs), three-dimensional (3D) transistors, or vertical FETs. Also, the semiconductor devices according to some embodiments of the present disclosure may include planar transistors. Also, the semiconductor devices according to some embodiments of the present disclosure may be applicable to two-dimensional (2D) material-based FETs and heterostructures thereof. Also, the semiconductor devices according to some embodiments of the present disclosure may include bipolar junction transistors or laterally-diffused metal-oxide semiconductor (LDMOS) transistors.

A semiconductor device according to some embodiments of the present disclosure will hereinafter be described with reference to FIGS. 1 through 5.

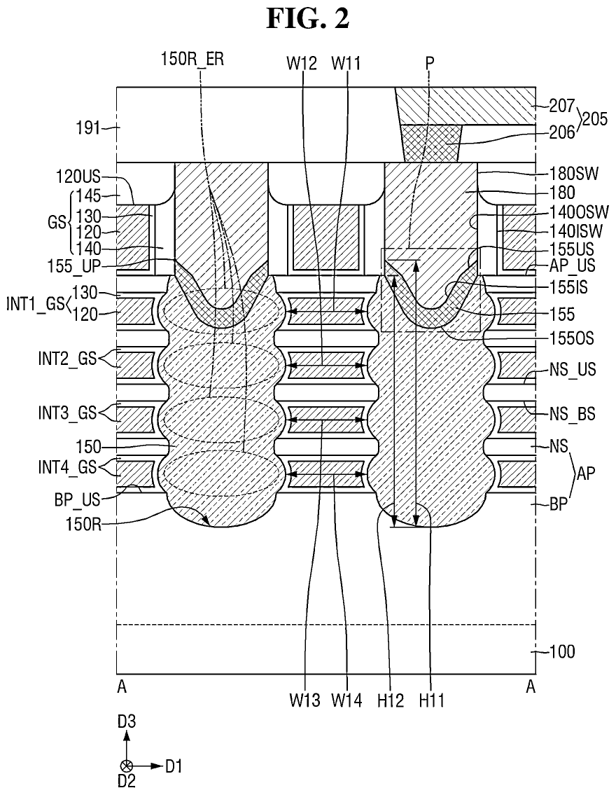

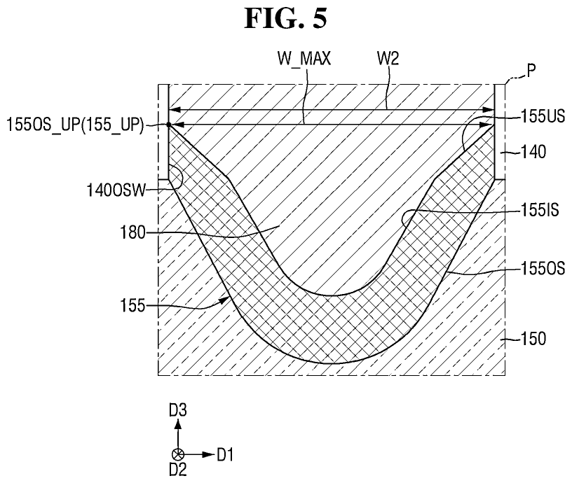

FIG. 1 is a layout view of a semiconductor device according to some embodiments of the present disclosure. FIGS. 2 through 4 are cross-sectional views taken along lines A-A, B-B, and C-C of FIG. 1. FIG. 5 is an enlarged cross-sectional view of part P of FIG. 2. For convenience, a wiring structure 205 is not illustrated in FIG. 1.

Referring to FIGS. 1 through 5, the semiconductor device according to some embodiments of the present disclosure may include an active pattern AP, a plurality of gate structures GS, source/drain patterns 150, contact silicide films 155, source drain contacts 180.

A substrate 100 may be formed of, or include, a semiconductor material. The substrate 100 may be a silicon (Si) substrate or a silicon-on-insulator (SOI) substrate. Alternatively, the substrate 100 may be a silicon substrate or may include another material such as, for example, silicon-germanium (SiGe), SiGe-on-insulator (SGOI), indium antimonide, a lead tellurium compound, indium arsenide, indium phosphide, gallium arsenide, or gallium antimonide, but the present disclosure is not limited thereto.

The active pattern AP may be disposed on the substrate 100. The active pattern AP may extend in a first direction D1. For example, the active pattern AP may be disposed in a region where an n-type metal-oxide semiconductor (NMOS) is formed. In another example, the active pattern AP may be disposed in a region where a p-type metal-oxide semiconductor (PMOS) is formed.

The active pattern AP may be, for example, a multi-channel active pattern. The active pattern AP may include a lower pattern BP and a plurality of sheet patterns NS. The active pattern AP may be an active pattern including nanosheets or nanowires.

The lower pattern BP may protrude from the substrate 100. The lower pattern BP may extend in the first direction D1.

The sheet patterns NS may be disposed on the lower pattern BP. The sheet patterns NS may be spaced apart from an upper surface BP_US of the lower pattern BP in a third direction D3. The sheet patterns NS may be spaced apart from one another in the third direction D3.

Each of the sheet patterns NS may have an upper surface NS_US and a bottom surface NS_BS. The upper surface NS_US and the bottom surface NS_BS may be opposite to each other in the third direction D3. Four sheet patterns NS are illustrated as being arranged in the third direction D3, but the present disclosure is not limited thereto.

The sheet patterns NS may include an uppermost sheet pattern NS spaced most apart from the upper surface BP_US of the lower pattern BP. For example, an upper surface AP_US of the active pattern AP may correspond to the upper surface NS_US of the uppermost sheet pattern NS.

Here, the third direction D3 may intersect the first direction D1 and a second direction D2. The first direction D1 may intersect the second direction D2. For example, the third direction D3 may be the thickness direction of the substrate 100.

The lower pattern BP may be formed by etching part of the substrate 100 or may include an epitaxial layer grown from the substrate 100. The lower pattern BP may include an element semiconductor material such as, for example, Si or germanium (Ge). Also, the lower pattern BP may include a compound semiconductor such as, for example, a group IV-IV compound semiconductor or a group III-V compound semiconductor.

The group IV-IV compound semiconductor may be, for example, a binary or ternary compound containing at least two of, Si, Ge, and tin (Sn) or a compound obtained by doping the binary or ternary compound with a group IV element.

The group III-V compound semiconductor may be, for example, a binary, ternary, or quaternary compound obtained by combining at least one of aluminum (Al), gallium (Ga), and indium (In), which are group III elements, and one of phosphorus (P), arsenic (As), and antimony (Sb), which are group V elements.

The sheet patterns NS may include one of an element semiconductor material (e.g., Si or Ge), the group IV-IV compound semiconductor, and the group III-V compound semiconductor. The sheet patterns NS may include the same material as, or a different material from, the lower pattern BP.

The lower pattern BP may be a Si lower pattern containing Si, and the sheet patterns NS may be Si sheet patterns containing Si.

The width, in a second direction D2, of the sheet patterns NS may increase or decrease in proportion to the width, in the second direction D2, of the lower pattern BP. For example, the width, in the second direction D2, of the sheet patterns NS, which are stacked in the third direction D3, may be uniform, but the present disclosure is not limited thereto. Alternatively, the width, in the second direction D2, of the sheet patterns NS, which are stacked in the third direction D3, may decrease away from the lower pattern BP.

A field insulating film 105 may be disposed on the substrate 100. The field insulating film 105 may be disposed on sidewalls of the lower pattern BP. The field insulating film 105 may not be disposed on the upper surface BP_US of the lower pattern BP.

For example, the field insulating film 105 may generally cover the sidewalls of the lower pattern BP. Alternatively, the field insulating film 105 may cover only parts of the sidewalls of the lower pattern BP, in which case, part of the lower pattern BP may protrude beyond the upper surface of the field insulating film 105 in the third direction D3.

The sheet patterns NS may be located higher than the upper surface of the field insulating film 105. The field insulating film 105 may include, for example, an oxide film, a nitride film, an oxynitride film, or a combination thereof. The field insulating film 105 is illustrated as being a single film, but the present disclosure is not limited thereto.

A plurality of gate structures GS may be disposed on the substrate 100. The gate structures GS may extend in the second direction D2. The gate structures GS may be spaced apart from one another in the first direction D1. The gate structures GS may be adjacent to one another in the first direction D1. For example, the gate structures GS may be disposed on both sides of each of the source/drain patterns 150.

The gate structures GS may be disposed on the active pattern AP. The gate structures GS may intersect the active pattern AP. The gate structures GS may intersect the lower pattern BP. The gate structures GS may surround each of the sheet patterns NS.

Each of the gate structures GS may include, for example, a gate electrode 120, gate insulating film 130, gate spacers 140, and a gate capping pattern 145.

Each of the gate structures GS may include a plurality of inner gate structures (INT1_GS, INT2_GS, INT3_GS, and INT4_GS), which are disposed between the sheet patterns NS, which are adjacent to one another in the third direction D3 or between the lower pattern BP and the sheet patterns NS. The inner gate structures (INT1_GS, INT2_GS, INT3_GS, and INT4_GS) may be disposed between the upper surface BP_US of the lower pattern BP and the bottom surface NS_BS of a lowermost sheet pattern NS or between the top and bottom surfaces NS_US and NS_BS of a pair of adjacent sheet patterns NS that are opposite to each other in the third direction D3.

The number of inner gate structures (INT1_GS, INT2_GS, INT3_GS, and INT4_GS) may be proportional to the number of sheet patterns NS included in the active pattern AP. For example, the number of inner gate structures (INT1_GS, INT2_GS, INT3_GS, and INT4_GS) may be the same as the number of sheet patterns NS included in the active pattern AP. As the active pattern AP includes a plurality of sheet patterns NS, each of the gate structures GS may include a plurality of inner gate structures (INT1_GS, INT2_GS, INT3_GS, and INT4_GS).

The inner gate structures (INT1_GS, INT2_GS, INT3_GS, and INT4_GS) may be in contact with the upper surface BP_US of the lower pattern BP, the upper surfaces NS_US of the sheet patterns NS, and the bottom surfaces NS_BS of the sheet patterns NS. Bottom surfaces INT_GSB of the inner gate structures (INT1_GS, INT2_GS, INT3_GS, and INT4_GS) may face the upper surface BP_US of the lower pattern BP. Each of the inner gate structures (INT1_GS, INT2_GS, INT3_GS, and INT4_GS) may have top and bottom surfaces that are opposite to each other in the third direction D3. The bottom surfaces of the inner gate structures (INT1_GS, INT2_GS, INT3_GS, and INT4_GS) may be in contact with the upper surface BP_US of the lower pattern BP or the upper surfaces NS_US of the sheet patterns NS. The bottom surfaces of the inner gate structures (INT1_GS, INT2_GS, INT3_GS, and INT4_GS) may be in contact with the bottom surfaces NS_BS of the sheet patterns NS.

The inner gate structures (INT1_GS, INT2_GS, INT3_GS, and INT4_GS) may also be in contact with the source/drain in contact with the source/drain patterns 150. For example, the inner gate structures (INT1_GS, INT2_GS, INT3_GS, and INT4_GS) may be in direct contact with the source/drain patterns 150.

Each of the gate structures GS will hereinafter be described as including four inner gate structures.

Each of the gate structures GS may include first, second, third, and fourth inner gate structures INT1_GS, INT2_GS, INT3_GS, and INT4_GS. The first, second, third, and fourth inner gate structures INT1_GS, INT2_GS, INT3_GS, and INT4_GS may be sequentially disposed on the lower pattern BP.

The fourth inner gate structure INT4_GS may be disposed between the lower pattern BP and one of the sheet patterns NS. The fourth inner gate structure INT4_GS may be in contact with the upper surface BP_US of the lower pattern BP. The fourth inner gate structure INT4_GS may be disposed at a lowest location, among the inner gate structures (INT1_GS, INT2_GS, INT3_GS, and INT4_GS) of each of the gate structures GS. The fourth inner gate structure INT4_GS may be the lowermost inner gate structure.

Each of the first, second, and third inner gate structures INT1_GS, INT2_GS, and INT3_GS may be disposed between the sheet patterns NS, which are adjacent to one another in the third direction D3. The second and third inner gate structures INT2_GS and INT3_GS may be disposed between the first and fourth inner gate structures INT1_GS and INT4_GS.

The first inner gate structure INT1_GS may be disposed at a highest location, among the inner gate structures (INT1_GS, INT2_GS, INT3_GS, and INT4_GS) of each of the gate structures GS. The first inner gate structure INT1_GS may be in contact with the bottom surface NS_BS of the uppermost sheet pattern NS. The first inner gate structure INT1_GS may be the uppermost inner gate structure.

Each of the inner gate structures (INT1_GS, INT2_GS, INT3_GS, and INT4_GS) may include the gate structure 120 and the gate insulating film 130 that are disposed between the sheet patterns NS or between the lower pattern BP and the sheet patterns NS.

For example, referring to FIG. 2, which is a cross-sectional, taken along the first direction D1, of the semiconductor device according to some embodiments of the present disclosure, a width W11 of the first inner gate structure INT1_GS may be the same as widths W12 and W13 of the second and third inner gate structures INT2_GS and INT3_GS. A width W14 of the fourth inner gate structure INT4_GS may be the same as the width W13 of the third inner gate structure INT3_GS.

For example, the width W12 of the second inner gate structure INT2_GS may be measured midway between the upper surface NS_US and the bottom surface NS_BS of two adjacent sheet patterns NS that are opposite to each other in the third direction D3.

Gate electrodes 120 may be formed on the lower pattern BP1. The gate electrode 120 may intersect the lower pattern BP. The gate electrodes 120 may surround the sheet patterns NS.

FIG. 2 illustrates that upper surfaces 120US of the gate electrodes 120 are flat, but the present disclosure is not limited thereto. Alternatively, the upper surfaces 120US of the gate electrodes 120 may be concave.

The gate electrodes 120 may include at least one of a metal, a metal alloy, a conductive metal nitride, a metal silicide, a doped semiconductor material, a conductive metal oxide, and a conductive metal oxynitride. The gate electrodes 120 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), Al, copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto. Here, the conductive metal oxide and the conductive metal oxynitride may include oxides of the aforementioned materials, but the present disclosure is not limited thereto.

The gate electrodes 120 may be disposed on both sides of the source/drain patterns 150 that will be described later. The gate structures GS may be disposed on both sides, in the first direction D1, of the source/drain patterns 150.

For example, gate electrodes 120 on both sides of each of the source/drain patterns 150 may be normal gate electrodes, which are used as the gates of transistors. In another example, a gate electrode 120 on one side of each of the source/drain patterns 150 may be used as the gate of a transistor, and a gate electrode 120 on the other side of each of the source/drain patterns 150 may be a dummy gate electrode.

Gate insulating films 130 may extend along the upper surface of the field insulating film 105 and the upper surface BP_US of the lower pattern BP. The gate insulating films 130 may surround the sheet patterns NS. The gate insulating films 130 may be disposed along the circumferences of the sheet patterns NS. The gate electrodes 120 may be disposed on the gate insulating films 130. The gate insulating films 130 may be disposed between the gate electrodes 120 and the sheet patterns NS.

The gate insulating films 130, which are included in the inner gate structures (INT1_GS, INT2_GS, INT3_GS, and INT4_GS), may be in contact with the source/drain patterns 150 that will be described later.

The gate insulating films 130 may include silicon oxide, silicon oxynitride, silicon nitride, or a high-k material having a greater dielectric constant than silicon oxide. The high-k material may include, for example, one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The gate insulating films 130 are illustrated as being single films, but the present disclosure is not limited thereto. Each of the gate insulating films 130 may include a plurality of films. The gate insulating films 130 may include interfacial films, which are disposed between the active pattern AP and the gate electrodes 120, and high-k insulating films. For example, the interfacial films may not be formed along the profiles of the upper surface of the field insulating film 105.

The semiconductor device according to some embodiments of the present disclosure may include negative capacitance (NC) FETs using negative capacitors. For example, the gate insulating films 130 may include ferroelectric material films having ferroelectric properties and paraelectric material films having paraelectric properties.

The ferroelectric material films may have a negative capacitance, and the paraelectric material films may have a positive capacitance. For example, if two or more capacitors are connected in series and have positive capacitance, the total capacitance of the two or more capacitors may be lower than the capacitance of each of the two or more capacitors. On the contrary, if at least one of the two or more capacitors has negative capacitance, the total capacitance of the two or more capacitors may have a positive value and may be greater than the absolute value of the capacitance of each of the two or more capacitors.

If the ferroelectric material films having a negative capacitance and the paraelectric material films having a positive capacitance are connected in series, the total capacitance of the ferroelectric material films and the paraelectric material films may increase. Accordingly, transistors having the ferroelectric material films can have a sub-threshold swing (SS) of less than 60 mV/decade at room temperature.

The ferroelectric material films may have ferroelectric properties. The ferroelectric material films may include, for example, at least one of hafnium oxide, hafnium zirconium oxide, barium strontium titanium oxide, barium titanium oxide, and lead zirconium titanium oxide. For example, the hafnium zirconium oxide may be a material obtained by doping hafnium oxide with zirconium (Zr). In another example, the hafnium zirconium oxide may be a compound of hafnium (Hf), Zr, and oxygen (O).

The ferroelectric material films may further include a dopant. For example, the dopant may include at least one of Al, Ti, Nb, lanthanum (La), yttrium (Y), magnesium (Mg), silicon, calcium (Ca), cerium (Ce), dysprosium (Dy), erbium (Er), gadolinium (Gd), germanium, scandium (Sc), strontium (Sr), and tin (Sn). The type of dopant may vary depending on the type of material of the ferroelectric material films.

If the ferroelectric material films include hafnium oxide, the dopant of the ferroelectric material films may include, for example, at least one of Gd, Si, Zr, Al, and Y.

If the dopant of the ferroelectric material films is Al, the ferroelectric material films may include 3 atomic % (at %) to 8 at % of Al. Here, the ratio of the dopant in the ferroelectric material films may refer to the ratio of the sum of the amounts of Hf and Al to the amount of Al in the ferroelectric material films.

If the dopant of the ferroelectric material films is Si, the ferroelectric material films may include 2 at % to 10 at % of Si. If the dopant of the ferroelectric material films is Y, the ferroelectric material films may include 2 at % to 10 at % of Y. If the dopant of the ferroelectric material films is Gd, the ferroelectric material films may include 1 at % to 7 at % of Gd. If the dopant of the ferroelectric material films is Zr, the ferroelectric material films may include 50 at % to 80 at % of Zr.

The paraelectric material films may include paraelectric properties. The paraelectric material films may include, for example, at least one of silicon oxide and a high-k metal oxide. The high-k metal oxide may include, for example, at least one of hafnium oxide, zirconium oxide, and aluminum oxide, but the present disclosure is not limited thereto.

The ferroelectric material films and the paraelectric material films may include the same material. The ferroelectric material films may have ferroelectric properties, but the paraelectric material films may not have ferroelectric properties. For example, if the ferroelectric material films and the paraelectric material films include hafnium oxide, the hafnium oxide included in the ferroelectric material films may have a different crystalline structure from the hafnium oxide included in the paraelectric material films.

The ferroelectric material films may be thick enough to exhibit ferroelectric properties. The ferroelectric material films may have a thickness of, for example, 0.5 nm to 10 nm, but the present disclosure is not limited thereto. A critical thickness that can exhibit ferroelectric properties may vary depending on the type of ferroelectric material, and thus, the thickness of the ferroelectric material films may vary depending on the type of ferroelectric material included in the ferroelectric material films.

For example, each of the gate insulating films 130 may include one ferroelectric material film. In another example, each of the gate insulating films 130 may include a plurality of ferroelectric material films that are spaced apart from one another. Each of the gate insulating films 130 may have a structure in which a plurality of ferroelectric material films and a plurality of paraelectric material films are alternately stacked.

Gate spacers 140 may be formed on the sidewalls of each of the gate electrodes 120. The gate spacers 140 may not be disposed between the lower pattern BP and the sheet patterns NS and between the sheet patterns NS, which are adjacent to one another in the third direction D3.

The gate spacers 140 may include inner sidewalls 140ISW and outer sidewalls 1400SW, which are opposite to the inner sidewalls 140ISW in the first direction D1. The inner sidewalls 140ISW of the gate spacers 140 may face the sidewalls of each of the gate electrodes 120.

The gate spacers 140 may include at least one of, for example, silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), and a combination thereof. The gate spacers 140 are illustrated as being single films, but the present disclosure is not limited thereto.

Gate capping patterns 145 may be disposed on the gate electrodes 120 and the gate spacers 140. The gate capping patterns 145 may cover the upper surfaces 120US of the gate electrodes 120 and the upper surfaces of the gate spacers 140.

Alternatively, the gate capping patterns 145 may be disposed between the gate spacers 140. The gate capping patterns 145 may not cover the upper surfaces of the gate spacers 140.

The gate capping patterns 145 may include at least one of, for example, SiN, SiON, SiCN, SiOCN, and a combination thereof. The gate capping patterns 145 may include a material having an etch selectivity with respect to an interlayer insulating film 190.

The source/drain patterns 150 may be disposed on the active pattern AP. The source/drain patterns 150 may be disposed on the lower pattern BP. The source/drain patterns 150 may be connected to the sheet patterns NS. The source/drain patterns 150 may be in contact with the sheet patterns NS.

The source/drain patterns 150 may be disposed on sides of the gate structures GS. The source/drain patterns 150 may be disposed between gate structures GS that are adjacent to one another in the first direction D1. For example, the source/drain patterns 150 may be disposed on both sides of each of the gate structures GS. Alternatively, the source/drain patterns 150 may be disposed on one side of each of the gate structures GS, but not on the other side of each of the gate structures GS.

The source/drain patterns 150 may be included in the sources/drains of each transistor using the sheet patterns NS as channel regions.

The source/drain patterns 150 may be disposed in source/drain recesses 150R. The source/drain patterns 150 may fill the source/drain recesses 150R.

The source/drain recesses 150R may extend in the third direction D3. The source/drain recesses 150R may be defined between the gate structures GS that are adjacent to one another in the first direction D1.

The bottom surfaces of the source/drain recesses 150R are defined by the lower pattern BP. The sidewalls of each of the source/drain recesses 150R may be defined by the sheet patterns NS and the inner gate structures (INT1_GS, INT2_GS, INT3_GS, and INT4_GS). Each of the inner gate structures (INT1_GS, INT2_GS, INT3_GS, and INT4_GS) may have an upper surface, a bottom surface, and sidewalls connecting the upper surface and the bottom surface. The sidewalls of each of the inner gate structures (INT1_GS, INT2_GS, INT3_GS, and INT4_GS) may define parts of the sidewalls of each of the source/drain recesses 150R.

The boundaries between the gate insulating films 130 and the lower pattern BP, between the lowermost sheet pattern NS and the lower pattern BP, may correspond to the upper surface BP_US of the lower pattern BP. The upper surface BP_US of the lower pattern BP may correspond to the boundary between the fourth inner gate structure INT4_GS and the lower pattern BP.

The bottom surfaces of the source/drain recesses 150R may be lower than the upper surface BP_US of the lower pattern BP. As the source/drain patterns 150 fill the source/drain recesses 150R, lowermost portions of the source/drain patterns 150 may be lower than the upper surface BP_US of the lower pattern BP.

The sidewalls of each of the source/drain recesses 150R may be wavy. Each of the source/drain recesses 150R may include a plurality of width-expanded regions 150R_ER. The width-expanded regions 150R_ER may be defined above the upper surface BP_US of the lower pattern BP.

The width-expanded regions 150R_ER may be defined between the sheet patterns NS, which are adjacent to one another in the third direction D3. The width-expanded regions 150R_ER may also be defined between the lower pattern BP and the sheet patterns NS. Each of the width-expanded regions 150R_ER may include a portion whose width in the first direction D1 increases away from the upper surface BP_US of the lower pattern BP and a portion whose width in the first direction D1 decreases away from the upper surface BP_US of the lower pattern BP. For example, the width of the width-expanded regions 150R_ER may increase and then decrease away from the upper surface BP_US of the first lower pattern BP.

The source/drain patterns 150 may be in contact with the sheet patterns NS and the lower pattern BP. The gate insulating films 130 of the inner gate structures (INT1_GS, INT2_GS, INT3_GS, and INT4_GS) may be in contact with the source/drain patterns 150.

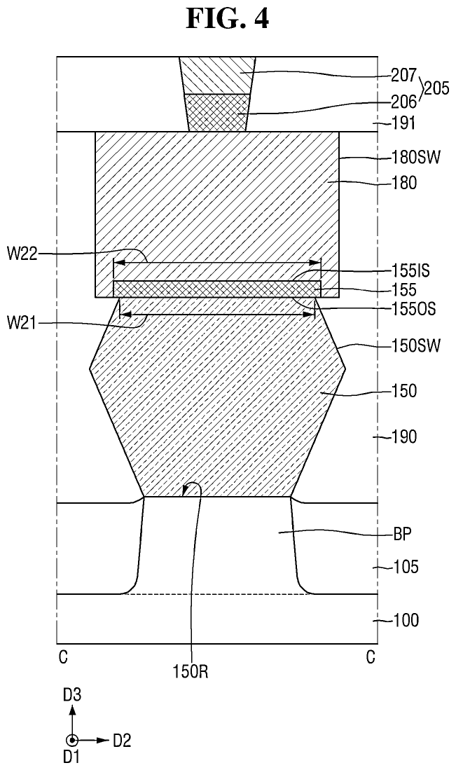

Each of the source/drain patterns 150 may have sidewalls 150SW, which extend in the third direction D3. The sidewalls 150SW of each of the source/drain patterns 150 may extend in the third direction D3 from the boundaries between the lower pattern BP and the source/drain patterns 150. FIG. 4 illustrates that the sidewalls 150SW include facet intersections where inclined surfaces meet, but the present disclosure is not limited thereto. Alternatively, the sidewalls 150SW may not include the facet intersections.

The source/drain patterns 150 may include epitaxial patterns. The source/drain patterns 150 may include a semiconductor material. The source/drain patterns 150 are illustrated as being single films, but the present disclosure is not limited thereto.

The source/drain patterns 150 may include an element semiconductor material such as, for example, Si or Ge. Also, the source/drain patterns 150 may include a binary or ternary compound containing at least two of, Si, Ge, and tin (Sn) or a compound obtained by doping the binary or ternary compound with a group IV element.

The source/drain patterns 150 may include impurities doping a semiconductor material. For example, the source/drain patterns 150 may include n-type impurities. The n-type impurities may include at least one of phosphorus (P), arsenic (As), and antimony (Sb), and bismuth (Bi). In another example, the source/drain patterns 150 may include p-type impurities. The p-type impurities may include at least one of boron (B) and gallium (Ga).

The first interlayer insulating film 190 may be disposed on the source/drain patterns 150. The first interlayer insulating film 190 may cover the sidewalls 150SW of each of the source/drain patterns 150. The first interlayer insulating film 190 may not cover the upper surfaces of the gate capping patterns 145.

The first interlayer insulating film 190 may include at least one of, for example, silicon oxide, silicon nitride, silicon oxynitride, and a low-k material. The low-k material may have a dielectric constant less than 3.9, which is the dielectric constant of silicon oxide.

The source/drain contacts 180 may be disposed on the source/drain patterns 150. The source/drain contacts 180 may be connected to the source/drain patterns 150.

The source/drain contacts 180 may be disposed in the first interlayer insulating film 190. The first interlayer insulating film 190 may not cover the upper surfaces of the source/drain contacts 180. The upper surfaces of the source/drain contacts 180 may be disposed on the same plane as the upper surfaces of the gate capping patterns 145, but the present disclosure is not limited thereto.

Referring to FIG. 2, sidewalls 180SW of each of the source/drain contacts 180 may be in contact with the sidewalls of each of the gate structures GS. The first interlayer insulating film 190 may not be disposed between the gate structures GS and the source/drain contacts 180. For example, the sidewalls 180SW of each of the source/drain contacts 180 may be in contact with the outer sidewalls of the gate spacers 140 and the sidewalls of each of the gate capping patterns 145.

Referring to FIG. 4, the sidewalls 180SW of each of the source/drain contacts 180 may be in contact with the first interlayer insulating film 190. The sidewalls 180SW of each of the source/drain contacts 180 may be flat. For example, the sidewalls 180SW of each of the source/drain contacts 180 may be flat in a cross-sectional view.

The source/drain contacts 180 may have a single-layer structure. The source/drain contacts 180 may be formed of a single conductive material. The source/drain contacts 180 may have a single-conductive-layer structure. The source/drain contacts 180 may include impurities that may be introduced unintentionally during the formation of the source/drain contacts 180.

The source/drain contacts 180 may include, for example, a metal. The source/drain contacts 180 may include at least one of, for example, W, Mo, Ru, and Co, but the present disclosure is not limited thereto.

The contact silicide films 155 may be disposed between the source/drain contacts 180 and the source/drain patterns 150. The contact silicide films 155 may be in contact with the source/drain contacts 180 and the source/drain patterns 150.

The contact silicide films 155 may include outer surfaces 1550S and inner surfaces 155IS. The outer surfaces 1550S of the contact silicide films 155 may be in contact with the source/drain patterns 150. The inner surfaces 155IS of the contact silicide films 155 may be in contact with the source/drain contacts 180.

Referring to FIG. 2, the outer surfaces 1550S of the contact silicide films 155 may have convex curve portions. For example, the outer surfaces 1550S of the contact silicide films 155 may have a convex shape. The inner surfaces 155IS of the contact silicide films 155 may include concave curve portions. For example, the inner surfaces 155IS of the contact silicide films 155 may have a concave shape.

Referring to FIGS. 2 and 5, the contact silicide films 155 may include uppermost portions 155_UP. The outer surfaces 1550S of the contact silicide films 155 may include uppermost outer surface portions 155OS_UP, which are the most distant from the lowermost portions of the source/drain patterns 150. The uppermost portions 155_UP of the contact silicide films 155 may correspond to the uppermost outer surface portions 155OS_UP. The uppermost outer surface 155OS_UP may correspond to an uppermost end of an upper surface 155US of the contact silicide film 155.

The width, in the first direction D1, of the contact silicide films 155 may increase away from the substrate 100. The width, in the first direction D1, of the contact silicide films 155 may be measured based on the outer surfaces 1550S of the contact silicide films 155. The contact silicide films 155 may have a maximum width W_MAX in the first direction D1 in the uppermost portions 155_UP. The width, in the first direction D1, of the contact silicide films 155 may reach its maximum in the uppermost portions 155_UP.

The maximum width W_MAX, in the first direction D1, of the contact silicide films 155 in the uppermost portions 155_UP may be the same as a width W2, in the first direction D1, of the source/drain contacts 180.

Parts of the contact silicide films 155 may protrude upwardly beyond the upper surface AP_US of the active pattern AP. A height H11 from the lowermost portions of the source/drain patterns 150 to the uppermost portions 155_UP of the contact silicide films 155 may be greater than a height H12 from the lowermost portions of the source/drain patterns 150 to the upper surface AP_US of the active pattern AP. Alternatively, the height from the upper surface AP_US of the active pattern to the uppermost portions 155_UP of the contact silicide films 155 may be greater than the height from the upper surface BP_US of the lower pattern BP to the upper surface AP_US of the active pattern AP.

Some height measurements may be obtained and compared based on the lowermost portions of the source/drain patterns 150, but may be directly applicable to height measurements obtained and compared based on the upper surface BP_US of the lower pattern BP.

Parts of the outer surfaces 1550S of the contact silicide films 155 are in contact with the gate spacers 140. For example, parts of the outer surfaces 155OS of the contact silicide films 155 are in contact with the outer sidewalls 1400SW of the gate spacers 140.

Referring to FIG. 4, the contact silicide films 155 may protrude beyond the sidewalls 150SW of each of the source/drain patterns 150 in the third direction D3. The contact silicide films 155 may include connection surfaces connecting the inner surfaces 155IS and the outer surfaces 155OS. For example, extensions of the sidewalls 150SW of each of the source/drain patterns 150 may not be aligned with the connection surfaces of the contact silicide films 155. The slope of the extensions of the sidewalls 150SW of each of the source/drain patterns 150 may differ from the slope of the connection surfaces of the contact silicide films 155.

For example, parts of the contact silicide films 155 may protrude beyond the sidewalls 150SW of each of the source/drain patterns 150 in the second direction D2. A width W22, in the second direction D2, of the contact silicide films 155 at the boundaries between the source/drain patterns 150 and the contact silicide films 155 may be greater than a width W21, in the second direction D2, of the source/drain patterns 150.

Referring to FIG. 2, upper surfaces 155US of the contact silicide films 155 may connect the inner surfaces 155IS and the outer surfaces 155US. The upper surfaces 155US of the contact silicide films 155 may be planar. For example, the upper surfaces 155US of the contact silicide films 155 may be planes inclined with respect to the upper surface AP_US of the active pattern AP. The uppermost outer surface portions 155OS_UP of the contact silicide films 155 may be higher than uppermost portions of the inner surfaces 155IS of the contact silicide films 155.

The contact silicide films 155 may include, for example, a metal silicide material. For example, the contact silicide films 155 may include a metal silicide material containing the same metal(s) as the source/drain contacts 180. In another example, the contact silicide films 155 may include a metal silicide material containing different metals from the source/drain contacts 180.

The contact silicide films 155 may be formed by diffusing a metal into a semiconductor material (e.g., the source/drain patterns 150). In this case, the contact silicide films 155 may become close to the gate electrodes 120 of the gate structures GS. If the contact silicide films 155 are close to the gate electrodes 120 of the gate structures GS, short circuits may occur between the source/drain patterns 150 and the gate electrodes 120. As a result, the performance and the reliability of the semiconductor device according to some embodiments of the present disclosure can be lowered.

The contact silicide films 155 may be formed by diffusing the semiconductor material included in the source/drain patterns 150 into metal films. That is, even if the contact silicide films 155 are formed, the distance between the contact silicide films 155 and the gate electrodes 120 may be maintained. As the distance between the contact silicide films 155 and the gate electrodes 120 can be maintained, short circuits between the source/drain patterns 150 and the gate electrodes 120 can be prevented. As a result, the performance and the reliability of the semiconductor device according to some embodiments of the present disclosure can be improved.

A second interlayer insulating film 191 may be disposed on the first interlayer insulating film 190. The second interlayer insulting film 191 may include at least one of, for example, silicon oxide, silicon nitride, silicon oxynitride, and a low-k material.

The wiring structure 205 may be disposed in the second interlayer insulating film 191. The wiring structure 205 may be connected to the source/drain contacts 180. The wiring structure 205 may include a wiring line 207 and a wiring via 206.

The wiring line 207 and the wiring via 206 may include at least one of, for example, a metal, a conductive metal nitride, a conductive metal carbide, a conductive metal oxide, a conductive metal carbonitride, and a 2D material. The wiring line 207 and the wiring via 206 are illustrated as having a single-conductive-layer structure, but the present disclosure is not limited thereto. Alternatively, at least one of the wiring lines 207 and the wiring via 206 may have a conductive multilayer structure.

The wiring line 207 and the wiring via 206 are illustrated as being separate from each other, but the present disclosure is not limited thereto. Alternatively, the wiring line 207 and the wiring via 206 may be incorporated together with no boundaries therebetween.

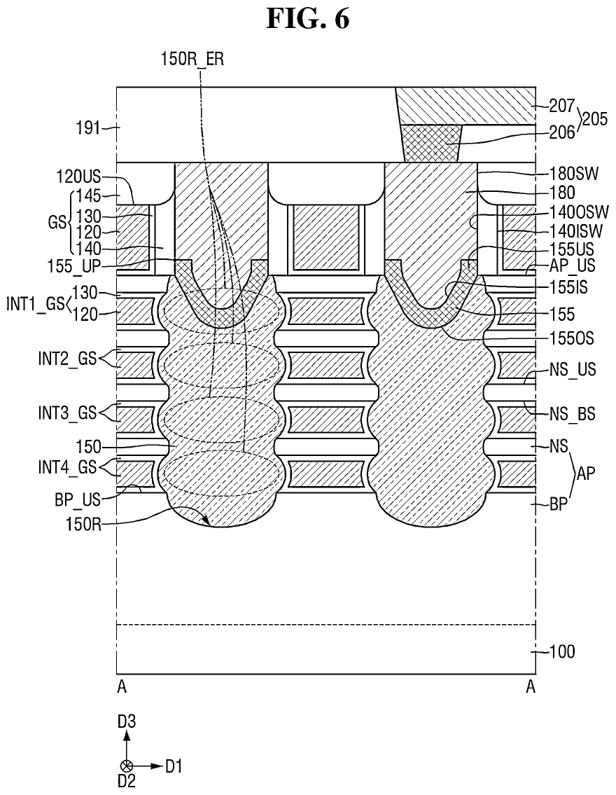

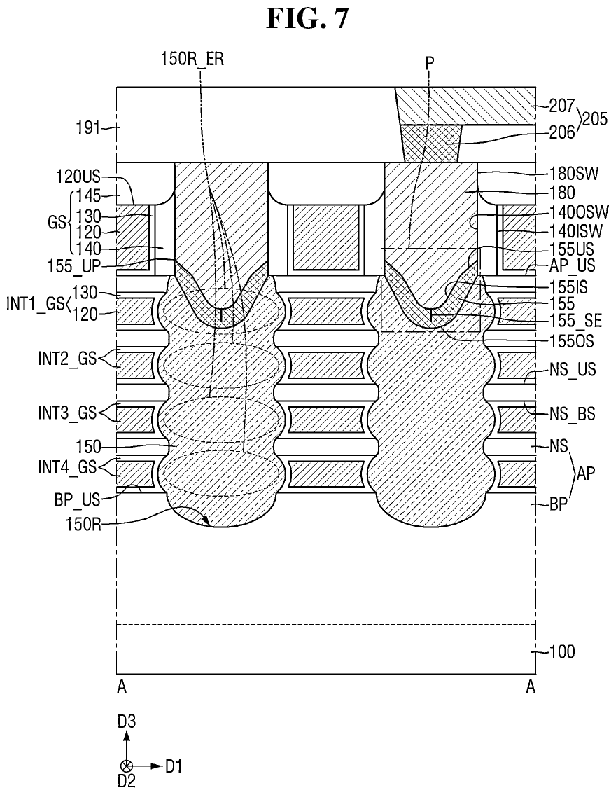

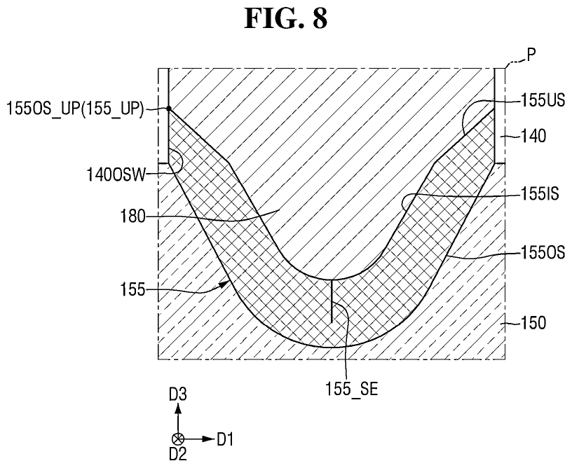

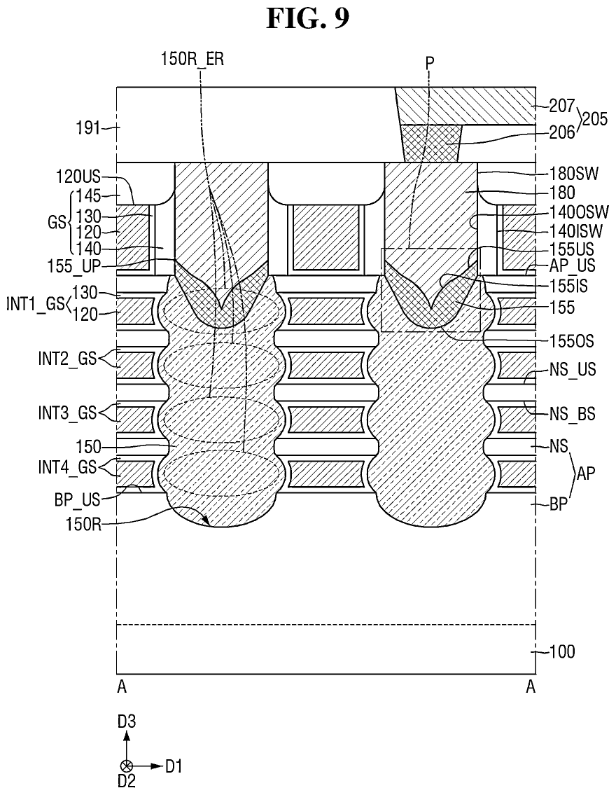

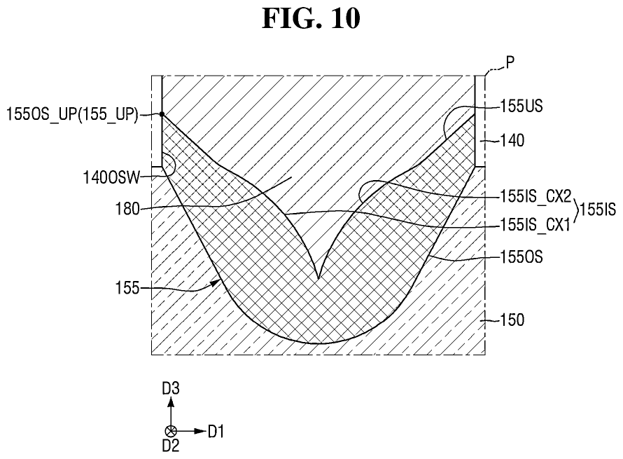

FIG. 6 is a cross-sectional view of a semiconductor device according to some embodiments of the present disclosure. FIGS. 7 and 8 are cross-sectional views of a semiconductor device according to some embodiments of the present disclosure. FIGS. 9 and 10 are cross-sectional views of a semiconductor device according to some embodiments of the present disclosure. For convenience, the embodiments of FIGS. 6 through 10 will hereinafter be described, focusing mainly on the differences with the embodiment of FIGS. 1 through 5. FIG. 8 is an enlarged cross-sectional view of part P of FIG. 7, and FIG. 10 is an enlarged cross-sectional view of part P of FIG. 9.

Referring to FIG. 6, upper surfaces 155US of contact silicide films 155 may be planes parallel to an upper surface AP_US of an active pattern AP.

Uppermost portions of outer surfaces 1550S of the contact silicide films 155 may be at the same height as uppermost portions of inner surfaces 155IS of the contact silicide films 155.

Referring to FIGS. 7 and 8, contact silicide films 155 may further include seam patterns 155_SE.

The seam patterns 155_SE may extend in a third direction D3. The seam patterns 155_SE may extend from inner surfaces 155IS of the contact silicide films 155 toward outer surfaces 1550S of the contact silicide films 155. The seam patterns 155_SE each may be a groove (or a boundary where two opposing surfaces of the contact silicide films 155 contact each other) extending from the inner surface 155IS to an inner region of a corresponding one of the contact silicide films 155.

For example, the seam patterns 155_SE may not extend to the outer surfaces 1550S of the contact silicide films 155. The contact silicide films 155 may not be separated by the seam patterns 155_SE.

Alternatively, the seam patterns 155_SE may extend to the outer surfaces 1550S of the contact silicide films 155. In some embodiments, the seam patterns 155_SE may be an opening (or a boundary where two opposing surfaces of the contact silicide films 155 contact each other) extending through the contact silicide films 155 in third direction D3.

Referring to FIGS. 9 and 10, inner surfaces 155IS of contact silicide films 155 may include first convex regions 155IS_CX1 and second convex regions 155IS_CX2.

The first convex regions 155IS_CX1 are connected to the second convex regions 155IS_CX2. The second convex regions 155IS_CX2 may have the shape of convex curves.

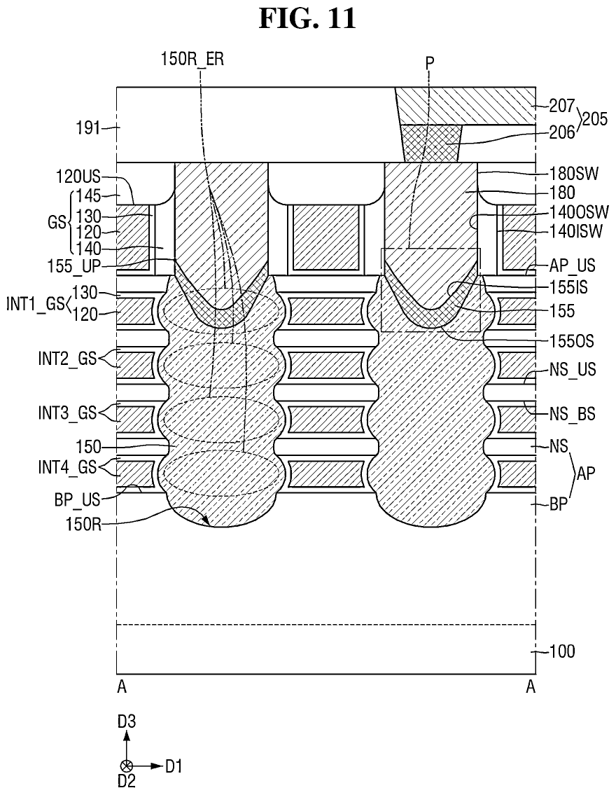

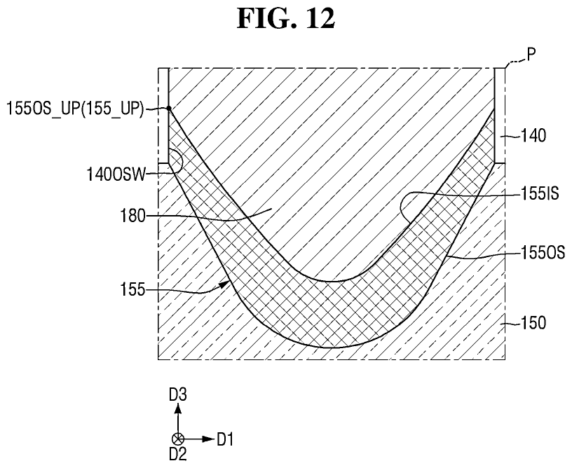

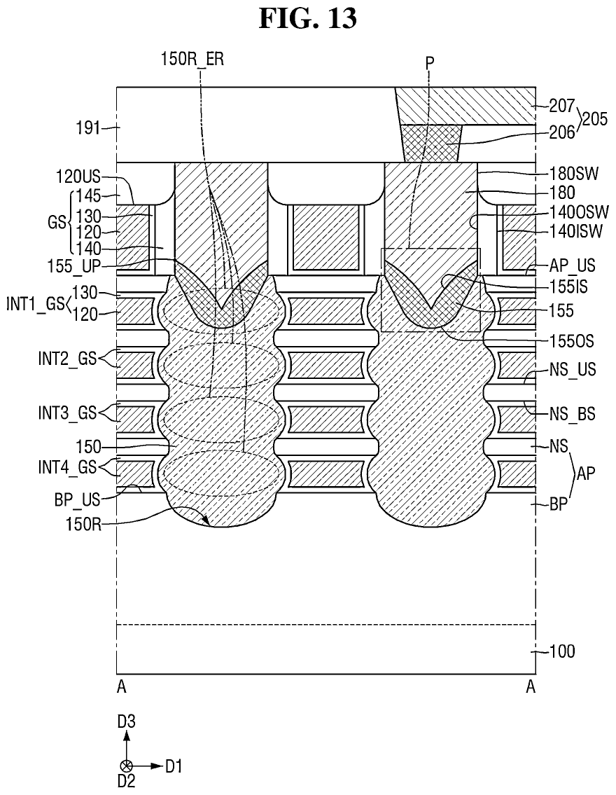

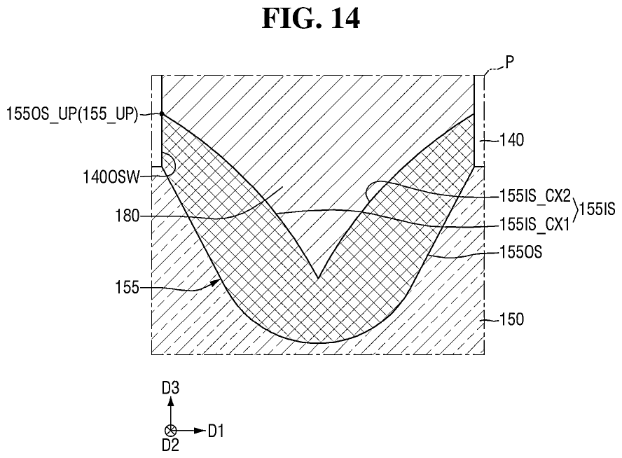

FIGS. 11 and 12 are cross-sectional views of a semiconductor device according to some embodiments of the present disclosure. FIGS. 13 and 14 are cross-sectional views of a semiconductor device according to some embodiments of the present disclosure. For convenience, the embodiments of FIGS. 11 through 14 will hereinafter be described, focusing mainly on the differences with the embodiment of FIGS. 1 through 5. FIG. 12 is an enlarged cross-sectional view of part P of FIG. 11, and FIG. 14 is an enlarged cross-sectional view of part P of FIG. 13.

Referring to FIGS. 11 through 14, inner surfaces 155IS of contact silicide films 155 may be directly connected to outer surfaces 1550S of the contact silicide films 155.

Uppermost portions of the inner surfaces 155IS of the contact silicide films 155 may correspond to uppermost outer surface portions 155OS_UP of the contact silicide films 155.

Referring to FIGS. 11 and 12, inner surfaces 155IS of contact silicide films 155 may include concave regions. The inner surfaces 155IS of the contact silicide films 155 may be directly connected to outer surfaces 1550S of the contact silicide films 155.

Referring to FIGS. 13 and 14, inner surfaces 155IS of contact silicide films 155 may include first convex regions 155IS_CX1 and second convex regions 155IS_CX2, which are directly connected to outer surfaces 1550S of the contact silicide films 155.

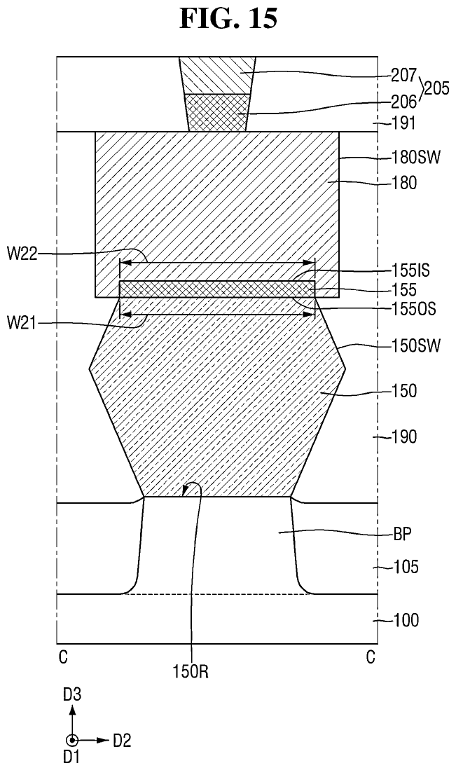

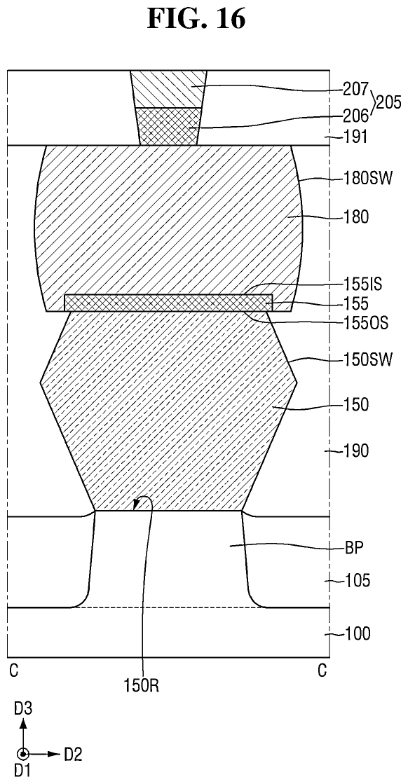

FIGS. 15 and 16 are cross-sectional views of a semiconductor device according to some embodiments of the present disclosure. For convenience, the embodiments of FIGS. 15 and 16 will hereinafter be described, focusing mainly on the differences with the embodiment of FIGS. 1 through 5.

Referring to FIG. 15, a width, in a second direction D2, of contact silicide films 155, at the boundaries between source/drain patterns 150 and the contact silicide films 155, may be the same as a width W21, in the second direction D2, of the source/drain patterns 150.

Parts of the contact silicide films 155 may not protrude beyond sidewalls 150SW of each of the source/drain patterns 150 in the second direction D2. For example, the slope of extensions of the sidewalls 150SW of each of the source/drain patterns 150 in the second direction D2 may differ from the slope of connection surfaces of the contact silicide films 155.

Referring to FIG. 16, sidewalls 180SW of each of source/drain contacts 180 may have a convex shape.

In a cross-sectional view, the sidewalls 180SW of each of the source/drain contacts 180 may include convex curves.

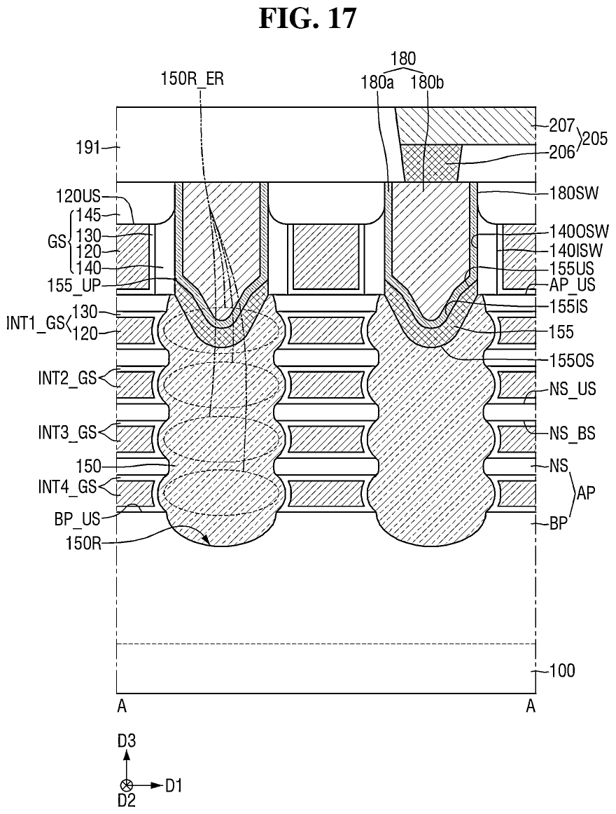

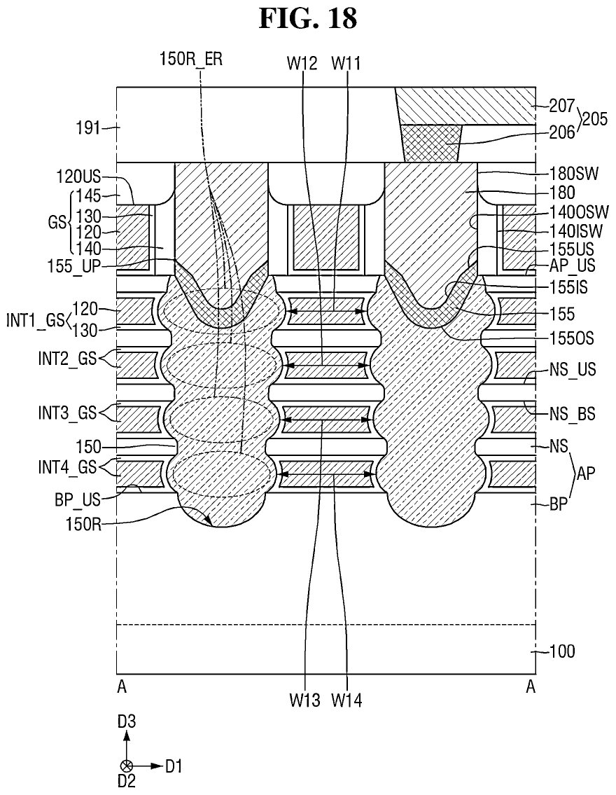

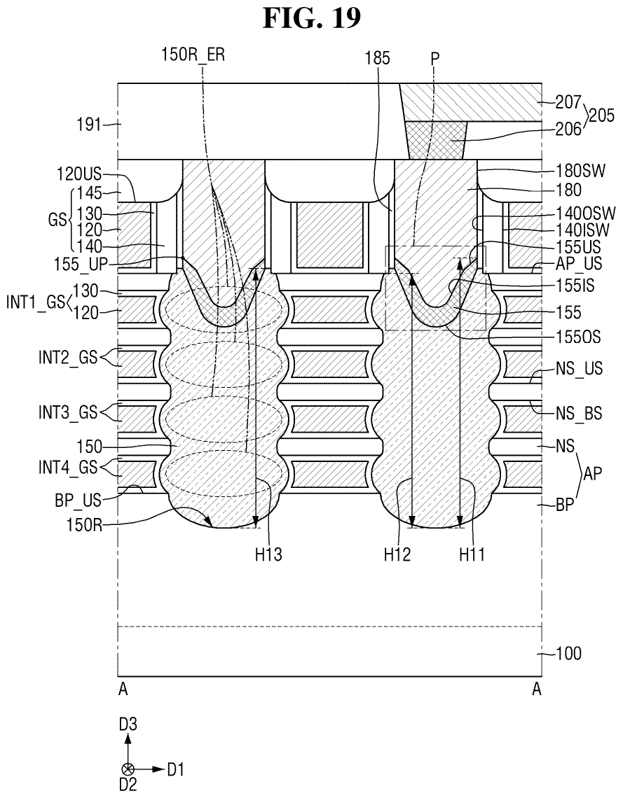

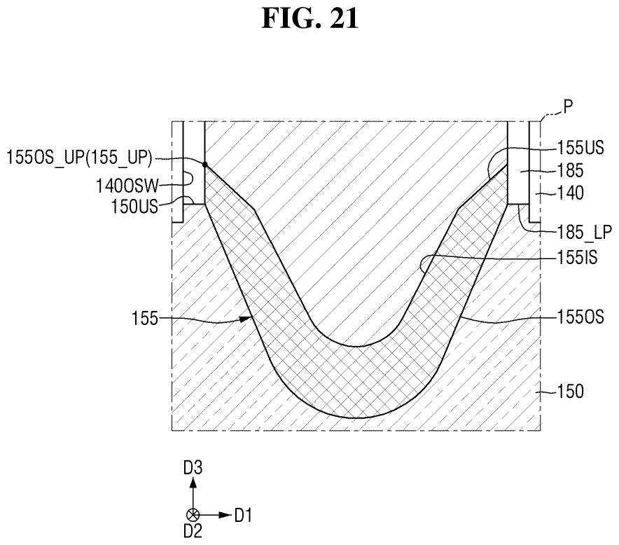

FIG. 17 is a cross-sectional view of a semiconductor device according to some embodiments of the present disclosure. FIG. 18 is a cross-sectional view of a semiconductor device according to some embodiments of the present disclosure. FIGS. 19 through 21 are cross-sectional views of a semiconductor device according to some embodiments of the present disclosure. For convenience, the embodiments of FIGS. 17 through 21 will hereinafter be described, focusing mainly on the differences with the embodiment of FIGS. 1 through 5. FIG. 21 is an enlarged cross-sectional view of part P of FIG. 19.

Referring to FIG. 17, source/drain contacts 180 may include contact barrier films 180a and contact plug films 180b.

The contact barrier films 180a may extend along the sidewalls of each of the contact plug films 180b. The contact barrier films 180a may be in contact with outer surfaces 1400SW of gate spacers 140 and the sidewalls of each of gate capping patterns 145. The contact barrier films 180a may be in contact with inner surfaces 155IS of contact silicide films 155.

The contact barrier films 180a may include at least one of, for example, a metal, a conductive metal nitride, a conductive metal carbide, a conductive metal oxide, a conductive metal carbonitride, and a 2D material. The contact plug films 180b may include, for example, a metal.

For example, the contact silicide films 155 may include a metal silicide material containing the same metal(s) as the contact barrier films 180a. In another example, the contact silicide films 155 may include a metal silicide material containing different metals from the contact barrier films 180a.

Referring to FIG. 18, a width W14 of a fourth inner gate structure INT4_GS may be greater than a width W13 of a third inner gate structure INT3_GS.

For example, a width W12 of a second inner gate structure INT2_GS may be less than the width W13 of the third inner gate structure INT3_GS. The width W12 of the second inner gate structure INT2_GS may be greater than a width W11 of a first inner gate structure INT1_GS.

Alternatively, the width W12 of a second inner gate structure INT2_GS may be the same as the width W11 of the first inner gate structure INT1_GS and the width W13 of the third inner gate structure INT3_GS.

Yet alternatively, the width W12 of a second inner gate structure INT2_GS and the width W13 of the third inner gate structure INT3_GS may be less than the width W11 of the first inner gate structure INT1_GS.

Referring to FIGS. 19 through 21, the semiconductor device according to some embodiments of the present disclosure may further include source/drain etch stopper films 185, which are disposed between gate structures GS and source/drain contacts 180.

The source/drain etch stopper films 185 may extend along outer surfaces 1400SW of gate spacers 140, sidewalls 150SW of each of source/drain patterns 150, and the upper surface of a field insulating film 105. The source/drain etch stopper films 185 may be in contact with the outer surfaces 1400SW of the gate spacers 140 and sidewalls 180SW of each of the source/drain contacts 180.

Referring to FIG. 19, the sidewalls of each of gate capping patterns 145 may be in contact with the sidewalls 180SW of each of the source/drain contacts 180. The gate capping patterns 145 may cover uppermost portions of the source/drain etch stopper films 185. Alternatively, parts of the source/drain etch stopper films 185 may be disposed between the sidewalls of each of the gate capping patterns 145 and the sidewalls 180SW of each of the source/drain contacts 180.

Referring to FIGS. 19 and 21, a height H13 from lowermost portions of the source/drain patterns 150 to upper surfaces 150US of the source/drain patterns 150 may be greater than a height H12 from the lowermost portions of the source/drain patterns 150 to an upper surface AP_US of an active pattern AP. In a case where the upper surfaces 150US of the source/drain patterns 150 protrude upwardly beyond the upper surface AP_US of the active pattern AP, parts of the source/drain patterns 150 may be disposed between the outer surfaces 1400SW of the gate spacers 140 and outer surfaces 155OS of contact silicide films 155.

The source/drain etch stopper films 185 may be in contact with the upper surfaces 150US of the source/drain patterns 150. The source/drain etch stopper films 185 may have bottom surfaces 185_LP, which are in contact with the upper surfaces 150US of the source/drain patterns 150.

Parts of the outer surfaces 1550S of the contact silicide films 155 may be in contact with the source/drain etch stopper films 185. Parts of the outer surfaces 1550S of the contact silicide films 155 may be in contact with side portions of the source/drain etch stopper films 185 that extend in a third direction D3. For example, the outer surfaces 1550S of the contact silicide films 155 may not be in contact with the outer surfaces 1400SW of the gate spacers 140.

A height H11 from the lowermost portions of the source/drain patterns 150 to uppermost portions 155_UP of the contact silicide films 155 may be greater than the height H13 from the lowermost portions of the source/drain patterns 150 to the bottom surfaces 185_LP of the source/drain etch stopper films 185.

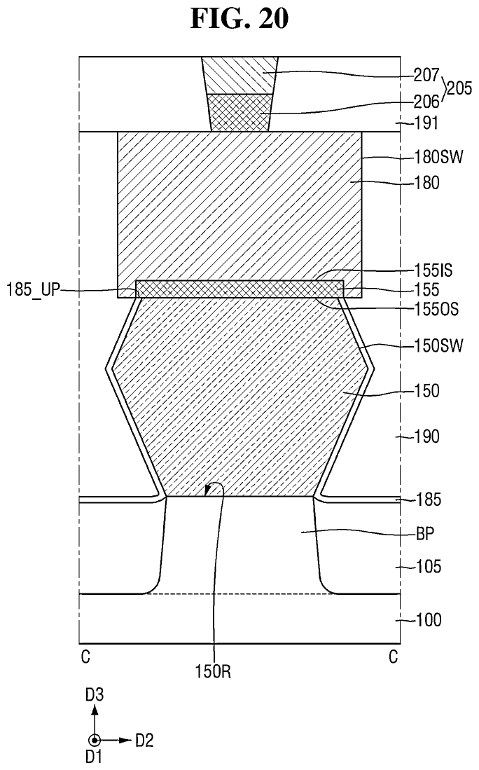

Referring to FIG. 20, the source/drain etch stopper films 185 may have upper surfaces 185_UP. In a cross-sectional view, the upper surfaces 185_UP of the source/drain etch stopper films 185 may be uppermost portions of the source/drain etch stopper films 185.

The contact silicide films 155 may be in contact with the upper surfaces 185_UP of the source/drain etch stopper films 185. The contact silicide films 155 may cover at least parts of the upper surfaces 185_UP of the source/drain etch stopper films 185.

The source/drain etch stopper films 185 may include a material having an etch selectivity with respect to an interlayer insulating film 190. The source/drain etch stopper films 185 may include at least one of, for example, SiN, SiON, SiOCN, SiBN, SiOBN, SiOC, and a combination thereof.

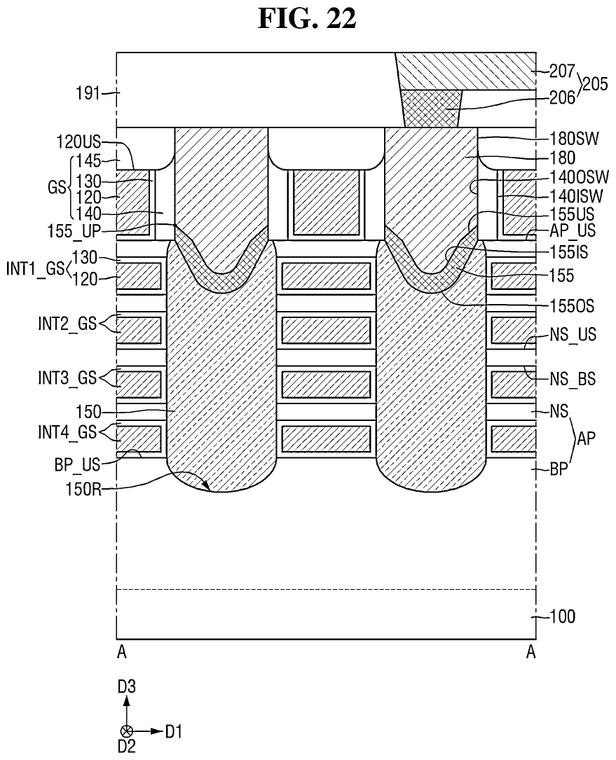

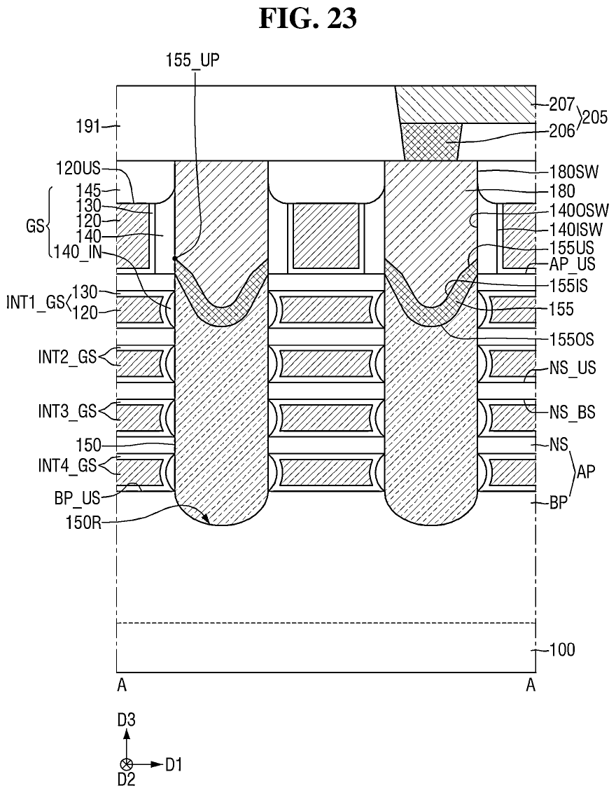

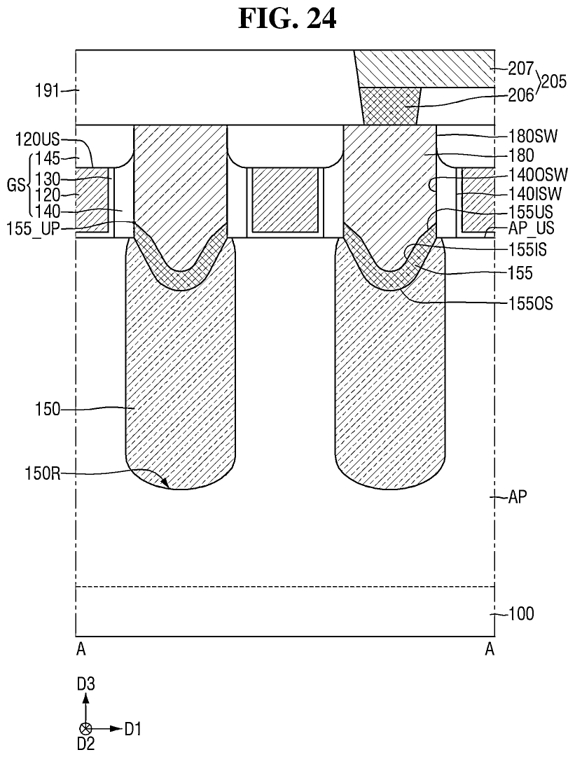

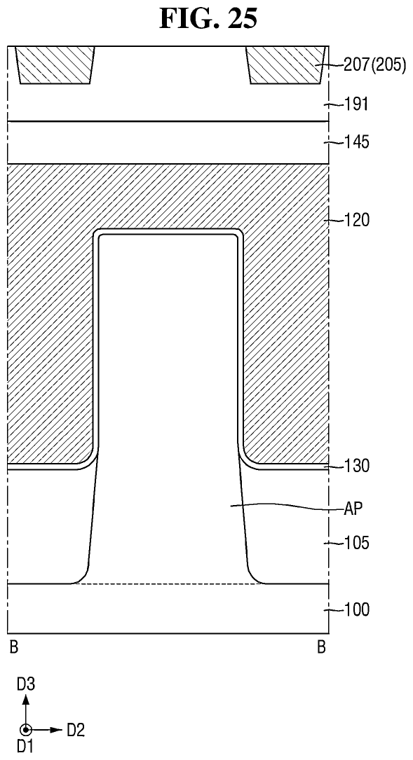

FIG. 22 is a cross-sectional view of a semiconductor device according to some embodiments of the present disclosure. FIG. 23 is a cross-sectional view of a semiconductor device according to some embodiments of the present disclosure. FIGS. 24 and 25 are cross-sectional views of a semiconductor device according to some embodiments of the present disclosure. For convenience, the embodiments of FIGS. 22 through 25 will hereinafter be described, focusing mainly on the differences with the embodiment of FIGS. 1 through 5.

Referring to FIG. 22, each of source/drain recesses 150R may not include a plurality of width-expanded regions (“150R_ER” of FIG. 2).

The sidewalls of each of the source/drain recesses 150R may not be wavy. The width, in a first direction D1, of upper portions of the sidewalls of each of the source/drain recesses 150R may decrease away from a lower pattern BP.

Referring to FIG. 23, each of gate structures GS may include a plurality of inner spacers 140_IN.

The inner spacers 140_IN may be disposed between sheet patterns NS, which are adjacent to one another in a third direction D3, and between a lower pattern BP and the sheet patterns NS. The inner spacers 140_IN may be disposed between an upper surface BP_US of the lower pattern BP and a bottom surface NS_BS of a lowermost sheet pattern NS and between top and bottom surfaces NS_US and NS_BS of every two adjacent sheet patterns NS that are opposite to each other in the third direction D3.

The inner spacers 140_IN are disposed between inner gate structures (INT1_GS, INT2_GS, INT3_GS, and INT4_GS) and source/drain patterns 150. The number of inner spacers 140_IN arranged in the third direction D3 is the same as the number of inner gate structures (INT1_GS, INT2_GS, INT3_GS, and INT4_GS).

The inner spacers 140_IN are in contact with the inner gate structures (INT1_GS, INT2_GS, INT3_GS, and INT4_GS). The inner gate structures inner gate structures (INT1_GS, INT2_GS, INT3_GS, and INT4_GS) are not in contact with the source/drain patterns 150.

The inner spacers 140_IN may include at least one of, for example, SiN, SiON, SiO₂, SiOCN, SiBN, SiOBN, SiOC, and a combination thereof.

Referring to FIGS. 24 and 25, an active pattern AP does not include sheet patterns (“NS” of FIG. 2).

The active pattern AP may be a fin pattern protruding upwardly beyond the upper surface of a field insulating film 105. The active pattern AP may be used as the channel region of each transistor including gate electrodes 120.

Each of gate structures GS may not include inner gate structures (“INT1_GS”, “INT2_GS”, “INT3_GS”, and “INT4_GS” of FIG. 2).

In concluding the detailed description, those skilled in the art will appreciate that many variations and modifications may be made to example embodiments of inventive concepts without substantially departing from the principles of inventive concepts. Therefore, the disclosed embodiments are used in a generic and descriptive sense only and not for purposes of limitation.

What is claimed is:

1. A semiconductor device comprising:
an active pattern extending in a first direction;
a plurality of gate structures on the active pattern and spaced apart from one another in the first direction, each of the plurality of gate structures including a gate electrode extending in a second direction and gate spacers on sidewalls of the gate electrode;
source/drain patterns between the plurality of gate structures that are adjacent to one another;
source/drain contacts on the source/drain patterns and connected to the source/drain patterns; and
contact silicide films between the source/drain contacts and the source/drain patterns, wherein
outer surfaces of the contact silicide films are in contact with the source/drain patterns, and inner surfaces of the contact silicide films are in contact with the source/drain contacts,
uppermost portions of the outer surfaces of the contact silicide films are uppermost portions of the contact silicide films,
a width in the first direction of the contact silicide films reaches its maximum at the uppermost portions of the outer surfaces of the contact silicide films,
parts of the outer surfaces of the contact silicide films are in contact with the gate spacers, and
the width in the first direction of the contact silicide films at the uppermost portions of the contact silicide films is equal to a width in the first direction of the source/drain contacts.

2. The semiconductor device of claim 1, wherein
the outer surfaces of the contact silicide films are convex, and
the inner surfaces of the contact silicide films are concave.

3. The semiconductor device of claim 2, wherein
the outer surfaces of the contact silicide films are directly connected to the inner surfaces of the contact silicide films.

4. The semiconductor device of claim 2, wherein
upper surfaces of the contact silicide films include upper surfaces, connect the outer surfaces of the contact silicide films and the inner surfaces of the contact silicide films, and
in a cross-sectional view, the upper surfaces of the contact silicide films are planes parallel to an upper surface of the active pattern.

5. The semiconductor device of claim 2, wherein
upper surfaces of the contact silicide films connect the outer surfaces of the contact silicide films and the inner surfaces of the contact silicide films, and
in a cross-sectional view, the upper surfaces of the contact silicide films are planes inclined with respect to an upper surface of the active pattern.

6. The semiconductor device of claim 1, wherein
the outer surfaces of the contact silicide films are convex, and
the inner surfaces of the contact silicide films include first convex regions and second convex regions, which are connected to each other.

7. The semiconductor device of claim 1, wherein
the contact silicide films further include seam patterns,
the seam patterns extend in a third direction, and
the third direction is perpendicular to the first direction and the second direction.

8. The semiconductor device of claim 1, wherein the source/drain contacts have a single-conductive-layer structure.

9. The semiconductor device of claim 1, wherein
the source/drain contacts each include a contact plug film and a contact barrier film, extending along sidewalls of the contact plug film.

10. The semiconductor device of claim 1, wherein
the active pattern includes a lower pattern and a plurality of sheet patterns,
the lower pattern extends in the first direction,
the plurality of sheet patterns are spaced apart from the lower pattern in a third direction,
each of the plurality of gate structures further includes inner gate structures,
the inner gate structures are between the lower pattern and the plurality of sheet patterns and between the plurality of sheet patterns that are adjacent to one another.

11. The semiconductor device of claim 10, wherein
each of the plurality of gate structures includes a gate insulating film, and
the gate insulating film in each of the inner gate structures is in contact with the source/drain patterns.

12. A semiconductor device comprising:
an active pattern including a lower pattern and a plurality of sheet patterns, the lower pattern extending in a first direction on a substrate, the plurality of sheet patterns being spaced apart from the lower pattern in a second direction, and the plurality of sheet patterns including an uppermost sheet pattern;
a plurality of gate structures on the lower pattern and spaced apart from one another in the first direction, each of the plurality of gate structures including a gate electrode extending in a third direction and gate spacers on sidewalls of the gate electrode;
source/drain patterns on the lower pattern and connected to the plurality of sheet patterns;
source/drain contacts on the source/drain patterns and connected to the source/drain patterns; and
contact silicide films between the source/drain contacts and the source/drain patterns, wherein
outer surfaces of the contact silicide films are in contact with the source/drain pattern, and inner surfaces of the contact silicide films are in contact with the source/drain contacts,
inner sidewalls of the gate spacers face the gate electrode and outer sidewalls of the gate spacers are opposite the inner sidewalls in the first direction,
parts of the outer surfaces of the contact silicide films are in contact with the outer sidewalls of the gate spacers,
a width in the first direction of the contact silicide films increases as a distance of the contact silicide films away from the substrate increases, and
a width in the first direction of the contact silicide films at uppermost portions of the contact silicide films is equal to a width in the first direction of the source/drain contacts.

13. The semiconductor device of claim 12, wherein
the outer surfaces of the contact silicide films are convex, and
the inner surfaces of the contact silicide films are concave.

14. The semiconductor device of claim 12, wherein
the outer surfaces of the contact silicide films are convex, and
the inner surfaces of the contact silicide films include first convex regions and second convex regions.

15. The semiconductor device of claim 12, wherein
the contact silicide films further include seam patterns,
the seam patterns extend in the second direction, and
the seam patterns do not extend to the outer surfaces of the contact silicide films.

16. The semiconductor device of claim 12, wherein
each of the plurality of gate structures further includes inner gate structures,
the inner gate structures are between the lower pattern and the plurality of sheet patterns and between the plurality of sheet patterns that are adjacent to one another,
the inner gate structures include a first inner gate structure and a second inner gate structure,
the second inner gate structure is between the lower pattern and the first inner gate structure, and
a width in the first direction of the first inner gate structure is less than a width in the first direction of the second inner gate structure.

17. The semiconductor device of claim 12, wherein
each of the plurality of gate structures further includes inner gate structures,
the inner gate structures are between the lower pattern and the plurality of sheet patterns and between the plurality of sheet patterns that are adjacent to one another,
the inner gate structures include a first inner gate structure and a second inner gate structure,
the second inner gate structure is between the lower pattern and the first inner gate structure, and
a width in the first direction of the first inner gate structure is equal to a width in the first direction, of the second inner gate structure.

18. A semiconductor device comprising:
an active pattern including a lower pattern and a plurality of sheet patterns, the lower pattern extending in a first direction, the plurality of sheet patterns being spaced apart from the lower pattern in a second direction, and the plurality of sheet patterns including an uppermost sheet pattern;
a plurality of gate structures on the lower pattern and spaced apart from one another in the first direction, each of the plurality of gate structures including a gate electrode extending in a third direction and gate spacers on sidewalls of the gate electrode;
source/drain patterns on the lower pattern and connected to the plurality of sheet patterns;
source/drain contacts on the source/drain patterns and connected to the source/drain patterns; and
contact silicide films between the source/drain contacts and the source/drain patterns, wherein
outer surfaces of the contact silicide films are in contact with the source/drain patterns,
inner surfaces of the contact silicide films in contact with the source/drain contacts,
upper surfaces of the contact silicide films connect the outer surfaces of the contact silicide films and the inner surfaces of the contact silicide films,
a height from lowermost portions of the source/drain patterns to uppermost portions of the contact silicide films is greater than a height from the lowermost portions of the source/drain patterns to an upper surface of the uppermost sheet pattern,
uppermost portions of the outer surfaces of the contact silicide films are higher than uppermost portions of the inner surfaces of the contact silicide films,
the outer surfaces of the contact silicide films are convex,
the inner surfaces of the contact silicide films are concave, and
in a cross-sectional view, the upper surfaces of the contact silicide films are planes inclined with respect to the upper surface of the uppermost sheet pattern.

19. The semiconductor device of claim 18, wherein
inner sidewalls of the gate spacers include face the gate electrode,
the inner sidewalls of the gate spacers are opposite outer sidewalls of the gate spacers in the first direction, and
parts of the outer surfaces of the contact silicide films are in contact with the outer sidewalls of the gate spacers.

20. The semiconductor device of claim 18, wherein
the contact silicide films further include seam patterns,
the seam patterns extend in the second direction, and
the seam patterns do not extend to the outer surfaces of the contact silicide films.
